(19) United States
(12) Patent Application Publication
(10) Pub. No.: US 2013/0300416 A1
(43) Pub. Date: Nov. 14, 2013

(54) INTERLEAVED SPIN-LOCKING IMAGING

(71) Applicant: Edward Brian Welch, Nashville, TN (US)

(72) Inventor: Edward Brian Welch, Nashville, TN (US)

(73) Assignee: KONINKLIJKE PHILIPS N.V., EINDHOVEN (NL)

(21) Appl. No.: 13/981,132

(22) PCT Filed: Jan. 24, 2012
(86) PCT No.: PCT/IB12/50314

§ 371 Date: Jul. 23, 2013

Related U.S. Application Data
(60) Provisional application No. 61/435,844, filed on Jan. 25, 2011.

(51) Int. Cl. G01R 33/32

(52) U.S. Cl. CPC G01R 33/32
USPC 324/309; 324/322

(57) ABSTRACT

A magnetic resonance (MR) system 10 includes a scan controller 20 which generates a plurality of like MR pulse sequences TR. Each pulse sequence includes a plurality (m) of RF excitation pulses EXC which selectively excite a nuclear species, a plurality of different spin lock pulses SL₁, SL₂, SLₘ before each RF excitation pulse EXC, a plurality of data readout intervals RE₁, RE₂, . . . , REₘ. A SAR unit 42 determines a SAR value corresponding to the pulse sequence and determines a shortest repetition time for the pulse sequence based on the SAR value. A plurality of pulse sequences TR are applied, each corresponds to a single phase encode. The pulse sequences are identical except for the phase encode gradients such that a plurality of T₁ₚ-weighted images of the examination region are generated. A T₁ₚ processor 40 analyzes the T₁ₚ-weighted images and generates a T₁ₚ map of the examination region according to the analysis.

The present application relates to the magnetic resonance arts. It finds particular application in spin-lattice relaxation pulse sequences for magnetic resonance imaging and magnet resonance spectroscopy.

Magnetic resonance imaging (MRI) and spectroscopy (MRS) systems are often used for the examination and treatment of patients. By such a system, the nuclear spins of the body tissue to be examined are aligned by a static main magnetic field B₀ and are excited by transverse magnetic fields B₁ oscillating in the radiofrequency band. In imaging, relaxation signals are exposed to gradient magnetic fields to localize the resultant resonance. The relaxation signals are received in order to form in a known manner a single or multi-dimensional image. In spectroscopy, information about the composition of the tissue is carried in the frequency component of the resonance signals.

MR tissue contrast depends on differences between T₁ and T₂ relaxation time, diffusion weighting, magnetization transfer, proton density, and the like to distinguish tissue. Another imaging technique, T_{1ρ}, utilizes the spin-lattice relaxation times in the rotating frame to provide additional means of generating contrast that is unlike conventional techniques. T_{1ρ}-weighted images are obtained by allowing magnetization to relax under the influence of an on-resonance, continuous wave RF pulse. In other words, the relaxation is obtained by spin-locking the magnetization in the transverse plane with the application of this low-power RF pulse. T_{1ρ}-weighted images show sensitivity to breast cancers, early acute cerebral ischemia, knee cartilage degeneration, post-traumatic cartilage injury, inter-vertebral discs, and brain activation and oxygen consumption.

Scan times for imaging acquisition using spin-locking RF pulses are often long, usually on the order of many minutes for a single T_{1ρ}-weighted acquisition depending on scan resolution and anatomical coverage, because of the increased RF energy exposed to the patient. The amount of RF energy per unit mass per unit time deposited into the patient during an imaging procedure is referred to as the specific absorption rate (SAR). The U.S. Food and Drug Administration has set limits on the amount of allowable SAR for an imaging procedure. Since the spin-lock RF pulses add a significant amount of SAR to the imaging procedure, the repetition interval between consecutive pulses are significantly lengthened to meet FDA guidelines which in turn lengthens the total scan times. Longer scan time are not only uncomfortable for the patient, but also increases the probably of motion artifacts. To reduce scan times, the scan resolution or anatomical coverage is often compromised.

In a typical T_{1ρ} sequence, in each repeat time (tᵣ) a spin-lock pulse is applied followed by an excitation pulse. After excitation, resonance manipulation pulses, phase encode pulses, and the like as are appropriate to the sequence are applied and data is read out. Finally, there is a pause of a minimum duration needed to meet the SAR requirements before the next tᵣ. A full image is generated with each of a plurality of spin-lock pulses and the corresponding voxels in the images are analyzed to generate the T_{1ρ} values for that voxel. In order to maintain the same phase evolution for all the images the same tᵣ is used for all of the images. The common tᵣ is selected based on the largest spin-lock pulse so that every tᵣ meets the SAR requirement

The present application provides a new and improved system and method which overcomes the above-referenced problems and others.

In accordance with one aspect, a magnetic resonance (MR) system is presented. The MR system includes a main magnet which generates a static magnetic field in an examination region. A radiofrequency (RF) coil generates a magnetic field to induce and manipulate magnetic resonance signals in a subject in the examination region and/or acquire magnetic resonance data therefrom. A scan controller controls at least one RF transmitter to generate a plurality of like MR pulse sequences transmitted via the RF coil. Each pulse sequence includes a plurality of RF excitation pulses which selectively excite a nuclear species, a plurality of different spin lock pulses before each RF excitation pulse; and a plurality of readout intervals.

In accordance with another aspect, method for magnetic resonance imaging is presented. The method includes generating a static magnetic field in an examination region. With an RF coil, generating a magnetic field to induce and manipulate magnetic resonance signals in a subject in the examination region and/or acquiring magnetic resonance data therefrom. At least one RF transmitter is controlled to generate a plurality of MR pulse sequences transmitted via the RF coil. Each pulse sequence includes a plurality of RF excitation pulses which selectively excite a nuclear species, a plurality of different spin lock pulses before each RF excitation pulse, and a plurality of readout intervals.

In accordance with another aspect, a method of generating a T_{1ρ} map of an examination region is presented. The method includes determining an MR sequence which includes a first spin lock pulse, a first excitation pulse, a phase encoding gradient, a first readout interval, a second spin lock pulse, a second excitation pulse, a phase encoding gradient, and a second readout interval. The pulse sequence is analyzed to determine a minimum repeat time that meets SAR requirements. The step of determining an MR pulse sequence is repeated with the minimum repeat time with different phase encode gradients to generate first and second data sets from data read out in the first and second read out intervals respectively. The first and second data sets are reconstructed to generate a first and second T_{1ρ}-weighted image. The first and second T_{1ρ}-weighted images are analyzed to generate the T_{1ρ} map.

One advantage is that the specific absorption rate (SAR) is reduced.

Another advantage is that the scan time for an imaging sequence is reduced.

Another advantage resides in a shorter repeat time.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

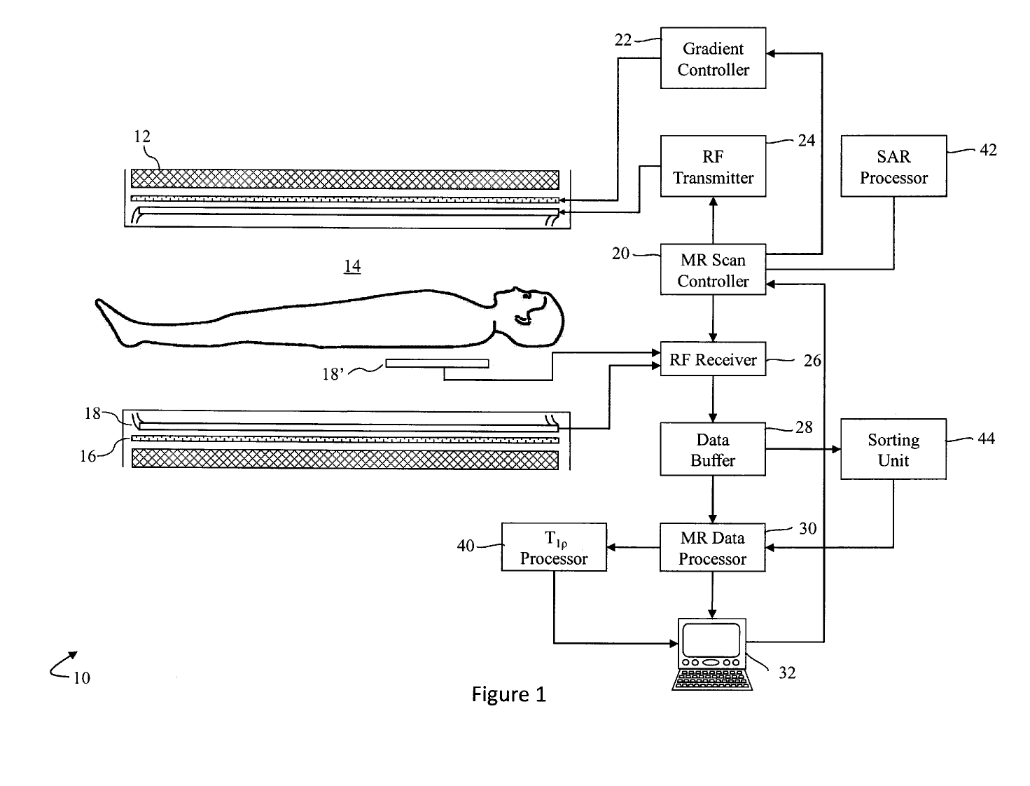

FIG. 1 is a diagrammatic illustration of a magnetic resonance system which produces the interleaved spin-locking pulse sequence;

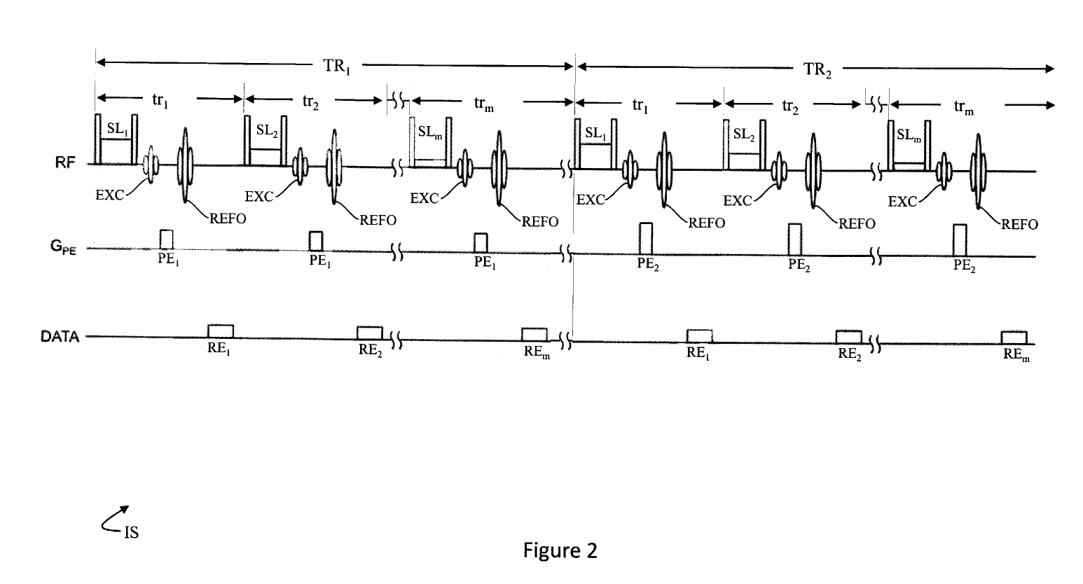

FIG. 2 is a graphical representation of a pulse sequence diagram for the interleaved spin-locking pulse sequence; and

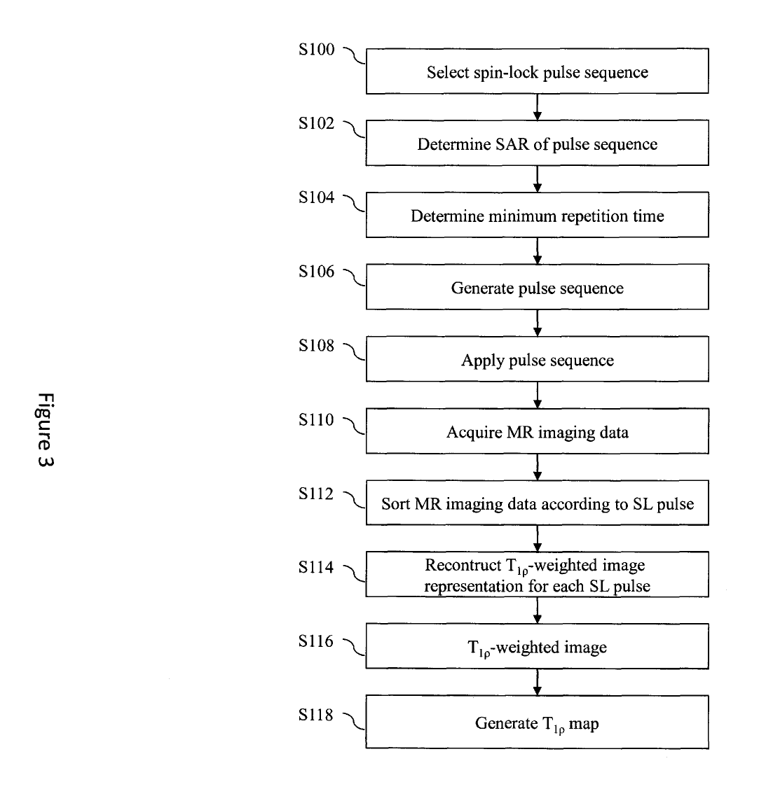

FIG. 3 is a method of magnetic resonance imaging with an interleave spin locking pulse sequence.

With reference to FIG. 1, a magnetic resonance imaging system 10 includes a main magnet 12 which generates a temporally uniform B₀ field through an examination region 14. The main magnet can be an annular or bore-type magnet, a C-shaped open magnet, other designs of open magnets, or the like. Gradient magnetic field coils 16 disposed adjacent the main magnet serve to generate magnetic field gradients along selected axes relative to the B₀ magnetic field. A radio frequency coil, such as a whole-body radio frequency coil 18 is disposed adjacent the examination region. Optionally, local or surface RF coils 18′ are provided in addition to or instead of the whole-body RF coil 18.

A scan controller 20 controls a gradient controller 22 which causes the gradient coils to apply selected phase encode gradients across the imaging region, as may be appropriate to a selected magnetic resonance imaging or spectroscopy sequence. The scan controller 20 also controls an RF transmitter 24 which causes the whole-body or local RF coils to generate magnetic resonance excitation and manipulation B₁ pulses. The scan controller also controls an RF receiver 26 which is connected to the whole-body or local RF coils to receive magnetic resonance signals therefrom.

The received data from the receiver 26 is temporarily stored in a data buffer 28 and processed by a magnetic resonance data processor 30. The magnetic resonance data processor can perform various functions as are known in the art, including image reconstruction, magnetic resonance spectroscopy, catheter or interventional instrument localization, and the like. Reconstructed magnetic resonance images, spectroscopy readouts, interventional instrument location information, and other processed MR data are displayed on a graphic user interface 32. The graphic user interface 32 also includes a user input device which a clinician can use for controlling the scan controller 20 to select scanning sequences and protocols, and the like.

To generate a T_{1ρ} map of the examination region 14, the MR system includes a T_{1ρ} processor 40 which analyzes a plurality image representations each with a different T_{1ρ}-weighting. Each is associated with a corresponding spin-lock pulse. Each spin-lock pulse has an RF power which is selected by adjusting the length of the pulse and/or the amplitude of the spin-lock pulse.

The T_{1ρ}-weighted image representations are generated during an imaging sequence during which a plurality of pulse sequences is applied to the examination region.

Before executing the pulse sequence, the specific absorption rate (SAR) of the pulse sequence is determined based on all of the RF pulses including the selected spin-lock pulses and the order at which they are applied. A SAR processor 42 determines the SAR value associated with the selected pulse sequence and determines a minimum repetition time that meets safety requirements.

With reference to FIG. 2, an imaging sequence includes a plurality of super repeat times TR. Each TR includes an m plurality of spin-lock pulses, excitation pulses, etc. More specifically, each TR includes m repeat times tr, i.e. tr₁, tr₂, . . . , trₘ, each including a spin-lock pulse SL, an excitation pulse EXC, a phase encode pulse PE, a refocusing pulse REFO (in the illustrated spin-echo sequence), and a readout interval RE. Other sequences may not have a refocusing pulse. Each TR includes one of each of the spin lock pulses SL₁, SL₂, . . . , SLₘ. In the illustrated embodiment, the same PE is applied in all of the tr's in each TR such that the same phase encode line is generated for each of the m images. The SAR processor 42 calculates the minimum TR. The SAR imposed delay or dead time before the next TR can being can be placed the end of the TR or distributed between the tr's. The distribution of the delay or dead time should be consistent in each TR to assure that the resonance sequence evolves constantly. By calculating the SAR over the different SL's, the SAR is effectively calculated based on an average of the SL's, not based on the largest SL.

As mentioned, each pulse sequence TRᵢ is associated with a single phase encode, e.g., a single phase encode line PEᵢ. After a pulse sequence TRᵢ completes, the gradient controller 22 adjusts the phase encode gradient PEᵢ₊₁ such that the subsequent pulse sequence TRᵢ₊₁ acquires MR imaging data at a different location in the examination region 14. Once MR imaging data is acquired from the entire examination region 14 for all of the spin-lock pulses SL₁, SL₂, . . . , SLₘ, a sorting unit 44 sorts the acquired MR imaging data according to the RF power of the spin-lock pulse SL.

Once the spin-lock sequence is selected at the GUI 32 by a clinician S100, the SAR processor 42 determines the minimum repetition time S102 of the consecutive like TR's based on the RF power associated with the corresponding spin-lock pulses SL, RF excitation pulses EXC, and optional RF refocusing pulses REFO for each like TR. The scanner controller 20 controls the RF transmitter 24 to generate S106 a spin-lock pulse sequence TR according to the determined minimum TR determined in step S104 and apply the pulse sequence S108 via the RF coil 18, 18′. In one embodiment, the same pulse sequence TR is applied consecutively for each phase encode gradient PE such as in the illustrated embodiment. data full set of k-space lines of the entire examination region 14 is acquired for each of the spin lock pulses SL₁, SL₂, . . . , SLₘ.

Continuing with the illustrated embodiment, each pulse sequence TR is associated with the same phase encode gradient PE. In other words, for the first pulse sequence TR₁ all of the subsequences tr₁, tr₂, . . . , trₘ are encoded with the same phase encode gradient PE₁ generated by the gradient controller 22 and applied by the gradient coils 16. For the second pulse sequence TR₂, all of the subsequences tr₁, tr₂, . . . , trₘ are encoded with the same phase encode gradient PE₂ and so on. After each phase encode gradient PE and optional RF refocusing pulse REFO, the RF receiver 26 receives the MR imaging data S110 during a readout interval RE. Each readout interval RE₁, RE₂, . . . , REₘ is associated with a corresponding unique spin-lock pulse SL₁, SL₂, . . . , SLₘ. The sorting unit 44 then sorts the acquired imaging data S112 according to the various readout interval RE during which it was acquired thus the imaging data is sorted according to the corresponding spin-lock pulse SL. The MR data processor 30 reconstructs an image representation of the examination region 14 for each unique spin-lock pulse SL using the sorted MR imaging data S114. Each image representation is a T_{1ρ}-weighted image representation. The T_{1ρ} processor 40 analyzes the T_{1ρ}-weighted image representations S116 to generate a T_{1ρ} map S118 of the examination region which is then displayed on the GUI 32 for the clinician to interpret.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A magnetic resonance (MR) system, comprising:
a main magnet which generates a static magnetic field in an examination region;
a radiofrequency (RF) coil which generates a magnetic field to induce and manipulate magnetic resonance signals in a subject in the examination region and/or acquire magnetic resonance data therefrom; and
a scan controller which controls at least one RF transmitter to generate a plurality of like MR pulse sequences transmitted via the RF coil, each pulse sequence including:
a plurality (m) of RF excitation pulses (EXC) which selectively excite a nuclear species;
a different one of a plurality of different spin lock pulses (SL₁, SL₂, . . . , SLₘ) before each of the RF excitation pulse (EXC); and
a readout interval (RE₁, RE₂, . . . , REₘ) after each of the RF excitation pulses.

2. The MR system according to claim 1, further including:
a specific absorption rate (SAR) unit which determines a SAR value corresponding to the pulse sequence (TR).

3. The MR system (10) according to claim 2, wherein the SAR unit determines a shortest repetition time according to the determined SAR value corresponding to the pulse sequence.

4. The MR system according to claim 1, further including:
a gradient controller which controls a gradient coil to apply a phase encode gradient (PE) after each RF excitation pulse (EXC) such that data readout in each readout interval corresponds to a single phase encode.

5. The MR system according to claim 4, wherein the scan controller controls the gradient controller to apply a unique phase encode gradient (PE) for each of the pulse sequences (TR).

6. The MR system according to claim 5, wherein each of the pulse sequences (TR) is identical except for the phase encode gradients.

7. The MR system according to claim 4, further including:
at least one RF receiver which acquires MR imaging data from the examination region after each phase encode gradient (PE).

8. The MR system according to claim 7, further including:
a sorting unit which sorts the acquired MR imaging data into data sets according to the RF power of the preceding spin lock pulse (SL); and
an MR data processor which reconstructs a T_{1ρ}-weighted image representation for each data set.

9. The MR system according to claim 8, further including:
a T_{1ρ} processor which analyzes the reconstructed image representation and generates a T_{1ρ} map of the examination region according to the analysis.

10. A method for magnetic resonance imaging, comprising:
generating a static magnetic field in an examination region;
with an RF coil, generating a magnetic field to induce and manipulate magnetic resonance signals in a subject in the examination region and/or acquiring magnetic resonance data therefrom; and
controlling at least one RF transmitter to generate a plurality of MR pulse sequences (TR) transmitted via the RF coil, each pulse sequence including:
a plurality (m) of RF excitation pulses (EXC) which selectively excite a nuclear species;
a different one of a plurality of different spin lock pulses (SL₁, SL₂, . . . , SLₘ) before each RF excitation pulse (EXC); and
a readout interval (RE₁, RE₂, . . . , REₘ) after each excitation pulse.

11. The method according to claim 10, further including:
determining a specific absorption rate (SAR) value corresponding to the pulse sequence (TR).

12. The method according to claim 11, further including:
determining a minimum repetition time of the pulse sequence (TR) according to the determined SAR value corresponding to the pulse sequence.

13. The MR system according to claim 10, further including:
applying a phase encode gradient (PE) after each RF excitation pulse (EXC) such that in each pulse sequence (TR) the readout data corresponding to a common phase encode, with each of the spin-lock weightings.

14. The method according to claim 13,
generating a plurality of pulse sequences (TR);
applying a unique phase encode gradient (PE) for each of the pulse sequences.

15. The method according to claim 10, wherein each of the pulse sequences (TR) are identical, except for the phase encode gradients.

16. The method according to claim 10, further including:
sorting data acquired in each of the readout intervals (RE₁, RE₂, . . . , REₘ) into data sets according to the RF power of the spin lock pulse (SL) preceding the corresponding phase encode gradient (PE); and
reconstructing a T_{1ρ}-weighted image representation for each data set.

17. The method according to claim 16, further including:
analyzing corresponding voxels of the reconstructed T_{1ρ}-weighted image representations; and
generating a T_{1ρ} map of the examination region according to the analysis.

18. A computer readable medium carrying software to control one or more processors to perform the method claim 10.

19. A method of generating a T_{1ρ} map of an examination region, the method comprising:
a) determining an MR sequence including:
a first spin lock pulse (SL₁);
a first excitation pulse (EXC);
a phase encoding gradient (PE);
a first readout interval (RE₁);
a second spin lock pulse (SL₂);
a second excitation pulse (EXC);
a phase encoding gradient (PE);
a second readout interval (RE₁);
b) analyzing the MR sequence determined in step (a) for a minimum repeat time that meets SAR requirements;
c) repeating step (a) with the minimum repeat time with different phase encode gradients to generate first and second data sets from data read out in the first and second red out intervals respectively;
d) reconstructing the first and second data sets to generate a first and second T_{1ρ}-weighted images; and
e) analyzing the first and second T_{1ρ}-weighted images to generate the T_{1ρ} map.

20. A system for generating T_{1ρ} map, the system comprising:
one or more processors programmed to perform the method according to claim 19.
